(19) United States
(12) Patent Application Publication
(10) Pub. No.: US 2019/0088809 A1
(43) Pub. Date: Mar. 21, 2019

(54) CONDUCTIVE INTERCONNECTION STRUCTURE FOR A GLASS-GLASS PHOTOVOLTAIC MODULE

(71) Applicant: EBFOIL S.R.L., Bologna (IT)

(72) Inventors: Elisa BACCINI, Carbonera (IT); Luigi MARRAS, Medea (IT); Bruno BUCCI, Castenaso (IT)

(21) Appl. No.: 16/078,589

(22) PCT Filed: Feb. 24, 2017
(86) PCT No.: PCT/IB2017/051072

§ 371 Date: Aug. 21, 2018

(30) Foreign Application Priority Data
Feb. 25, 2016 (IT) 102016000019394

(51) Int. Cl. H01L 31/05; H01L 31/048

(52) U.S. Cl. CPC H01L 31/05; H01L 31/0488

(57) ABSTRACT

The invention describes a conductive interconnection structure (10) to be applied to a photovoltaic module of the glass-glass type comprising: a conductive layer (200) comprising a predetermined layout of conductive material, a first lower layer (100) comprising encapsulating material and a second upper layer (300) comprising encapsulating material, wherein the conductive layer (200) is arranged between the first lower layer (100) and the second lower layer (300). The invention also describes a photovoltaic module (1000) of the glass-glass type comprising a conductive interconnection structure (10), a method for forming a conductive interconnection structure (10) for a photovoltaic module (1000) of the glass-glass type and a method for forming a photovoltaic module (1000) of the glass-glass type.

### TECHNICAL FIELD OF THE INVENTION

The present invention concerns the field of photovoltaic modules. In particular, the present invention concerns the field of photovoltaic modules of the glass-glass type. Even more in particular, the present invention concerns a conductive interconnection structure for a photovoltaic module of the glass-glass type.

### STATE OF THE ART

Glass-glass photovoltaic modules are photovoltaic modules that have protective layers of glass on both the front and rear surfaces of the module. In particular, glass-glass photovoltaic modules do not only have the layer of glass on the main surface facing directly towards the sun like conventional photovoltaic modules, but also on the opposite surface, i.e. on the rear surface of the module. In glass-glass photovoltaic modules, therefore, both of the air-sides of the module are made through layers or sheets of glass. The use of glass also on the rear side of the module is advantageous because the glass effectively protects the internal structures of the module from atmospheric agents. Moreover, the use of glass on the rear side of the module advantageously makes it possible to implement systems with double-faced solar cells, i.e. with cells that produce energy not only thanks to the radiation absorbed by their front surface directly facing towards the sun, but also thanks to the radiation absorbed by their rear surface. Moreover, glass-glass photovoltaic modules are very aesthetically beautiful and therefore are used widely in so-called Building Integrated Photo Voltaic (BIPV).

The purpose of the present invention is to provide a conductive interconnection structure for photovoltaic modules of the glass-glass type. The term “conductive interconnection structure” is meant to indicate a structure that assists in the physical connection of the various elements of the photovoltaic module, i.e. that allows the adhesion of the various elements of the photovoltaic module. At the same time, the attribute “conductive” indicates that the structure not only allows the physical-mechanical adhesion of the various elements of the module, but, at the same time, includes a conductive layer that is configured to make the various electrical connections necessary in the module itself. The conductive layer can thus be configured to connect together the solar cells of the module. Moreover, the conductive layer can be configured to supply the electrical connections of the module towards the outside, i.e. for connecting for example different photovoltaic modules together or even to connect the photovoltaic module with any component of a photovoltaic installation.

The purpose of the present invention is to provide a conductive interconnection structure that ensures optimal adhesion of the system and that can be made easily, so as to be able to keep the costs of the system down. In particular, the invention provides a solution that can be used for example for the connection of back-contact cells in glass-glass photovoltaic modules.

### SUMMARY

The present invention is based on the idea of providing a conductive interconnection structure for a photovoltaic module of the glass-glass type in which the predetermined layout of conductive material of the conductive interconnection structure is arranged above a layer comprising encapsulating material. In the present invention, the terms “above”, “below”, “lower” and “upper”, unless specified otherwise, refer to the relative arrangement of the various layers considering a section view of the final architecture of the glass-glass photovoltaic module in which the main surface of the photovoltaic module, i.e. the surface directly facing towards the sun, occupies the highest level.

According to an embodiment of the present invention, a conductive interconnection structure to be applied to a photovoltaic module of the glass-glass type is provided comprising: a conductive layer comprising a predetermined layout of conductive material, a first lower layer comprising encapsulating material and a second upper layer comprising encapsulating material, wherein the conductive layer is arranged between the first lower layer and the second lower layer. Based on the present invention, therefore, the predetermined layout of conductive material is supported by a layer that comprises encapsulating material. The presence of encapsulating material in the first lower layer is particularly advantageous because the adhesion of the conductive interconnection structure based on the present invention to the rear glass layer of the glass-glass photovoltaic module to which the conductive interconnection structure will be applied is promoted and optimised. Moreover, the presence of encapsulating material in the second upper layer is advantageous because the adhesion of the conductive interconnection structure to the solar cells of the glass-glass photovoltaic module and to the encapsulating material with which the solar cells are coupled with the upper glass layer, i.e. the main surface, of the glass-glass photovoltaic module is promoted and optimised. The presence of encapsulator on both sides of the conductive layer is also particularly advantageous because the adhesion of the first lower layer to the second upper layer is promoted and optimised thanks to the interaction of the materials of these two layers in the interspaces of the predetermined layout of conductive material. The conductive interconnection structure based on the present invention thus makes it possible to optimise the stability of glass-glass photovoltaic modules. Moreover, the conductive interconnection structure based on the present invention makes it possible to make glass-glass photovoltaic modules with back-contact cells. The fact that the conductive interconnection structure based on the present invention is “to be applied” to a photovoltaic module of the glass-glass type means that the conductive interconnection structure based on the present invention is a product on its own, i.e. a product that is made independently and separately with respect to the photovoltaic module and that, once made, will subsequently be incorporated in the photovoltaic module while it is made. This solution is particularly advantageous since it makes it possible to have an independent structure that can be applied directly to a photovoltaic module. This makes it possible to substantially reduce the mounting time of a photovoltaic module and to simplify the process thereof. The conductive interconnection structure based on the present invention can also be commercialised as an intermediate product to make photovoltaic modules.

Examples of encapsulating material of the layer of encapsulating material arranged below the predetermined layout of conductive material comprise: EVA (ethylene vinyl acetate), silicones, ionomer resins, thermo-polyurethanes, polyolefins, thermo-polyolefins, terpolymers seamed with maleic anhydride, PVB (polyvinylbutyrral).

The conductive material of the conductive layer can comprise copper. Moreover or alternatively, the conductive material can comprise aluminium. Moreover, in particular in the case in which the conductive material comprises aluminium, the conductive material can comprise a conductive metallic layer on the opposite surface to the surface that is fixed to the first lower layer. The conductive metallic layer can comprise silver or a metallic alloy comprising silver or copper or a metallic alloy comprising copper and can for example have a thickness comprised between 12 nm and 200 nm and, preferably, between 40 nm and 100 nm.

According to a further embodiment of the present invention, a conductive interconnection structure is provided in which the conductive layer is in direct contact with the encapsulating material of the first lower layer.

According to a further embodiment of the present invention, a conductive interconnection structure is provided in which the conductive layer is in direct contact with the encapsulating material of the second upper layer. Based on an embodiment, the conductive layer is in direct contact with the encapsulating material both on its lower surface and on its upper surface. Advantageously, the encapsulating material of the second upper layer in direct contact with the conductive layer is the same encapsulating material of the first lower layer in direct contact with the conductive layer. In this way, the adhesion of the system is optimised since, once lamination is complete, the conductive layer is inside a homogeneous layer formed from a single encapsulating material. As an alternative, this effect can be obtained by combining two encapsulating materials that are different but compatible with each other.

According to a further embodiment of the present invention, a conductive interconnection structure is provided, wherein the second upper layer comprises a plurality of through holes, wherein one or more or each of the through holes is at a conductive region of the predetermined layout of conductive material. The through holes can be used to make the electrical connection between the solar cells of the photovoltaic module and the layout of conductive material of the interconnection structure. For example, the through holes can house conductive adhesive so as to make the electrical connection between the rear side of the solar cells of the module and the layout of conductive material of the interconnection structure.

According to a further embodiment of the present invention, a conductive interconnection structure is provided, wherein the first lower layer comprises a layer of dielectric material arranged between a layer of thermo-adhesive material and a layer of encapsulating material. This multi-layer structure of the first lower layer is particularly advantageous because it optimises the assembly of the conductive interconnection structure with the rear glass layer of the glass-glass photovoltaic module to which the conductive interconnection structure will be applied. The stability and the adhesion of the various components of the system are optimised. The first lower layer can for example be structured to be produced as described in WO 2013/182954 A1 with reference to the “multi-layer structure”. The teaching of WO 2013/182954 A1 is incorporated here in its entirety. The first lower layer can also be produced for example as described in Italian patent application No. 102012902092055 (VI2012A000267) the teaching of which is incorporated here in its entirety.

According to a further embodiment of the present invention, a conductive interconnection structure is provided, wherein the second upper layer comprises a layer of dielectric material arranged between a layer of thermo-adhesive material and a layer of encapsulating material. This multi-layer structure of the first lower layer is particularly advantageous because it optimises the assembly of the conductive interconnection structure with the solar cells of the glass-glass photovoltaic module to which the conductive interconnection structure will be applied and with the encapsulating material that can be used to couple the solar cells with the upper glass layer, i.e. of the main surface, of the glass-glass photovoltaic module. The stability and the adhesion of the various components of the system are thus increased. The second upper layer can for example be structured and be produced as described in WO 2013/182954 A1 with reference to the “multi-layer structure”. The teaching of WO 2013/182954 A1 is incorporated here in its entirety. The second upper layer can also be produced for example as described in Italian patent application No. 102012902092055 (VI2012A000267) the teaching of which is incorporated here in its entirety.

According to a further embodiment of the present invention, a conductive interconnection structure is provided, wherein the thickness of the first lower layer is greater than the thickness of the second upper layer. The greater thickness of the lower layer makes it easier to machine and, in particular, to form the conductive layer with the predetermined layout of conductive material on its upper surface. The lower thickness of the upper layer, on the other hand, makes it possible to optimise the consumption of conductive material, for example conductive adhesive, which must be used to make the electrical contact between the photovoltaic cells of the module that contains the conductive interconnection structure according to the present invention and the conductive layer of the conductive structure.

For example, according to particularly advantageous embodiments of the present invention, the ratio between the thickness of the first lower layer and the thickness of the second upper layer is in the range from 1.5 to 2.5, preferably from 1.5 to 2.0, even more preferably it is equal to 1.75. These values of the ratios between the two thicknesses make it possible to optimise the workability of the system thanks to the thickness of the lower layer on one side and the consumption of conductive material thanks to the thickness of the upper layer on the other.

According to a further embodiment of the present invention, a conductive interconnection structure is provided, wherein the thickness of the first lower layer is comprised in the range from 250 micrometres to 500 micrometres, preferably from 300 micrometres to 400 micrometres, even more preferably it is equal to 350 micrometres. These values for the thickness of the first lower layer are particularly advantageous to ensure the workability of the system, to ensure that the first lower layer can encapsulate the inner parts of the module, in particular the conductive layer with the predetermined layout of conductive material, and to absorb possible rough areas of the system once laminated, thus minimising the presence of structural defects that could compromise the stability of the conductive interconnection structure.

According to a further embodiment of the present invention, a conductive interconnection structure is provided, wherein the thickness of the second upper layer is comprised in the range from 100 micrometres to 300 micrometres, preferably from 150 micrometres to 250 micrometres, even more preferably it is equal to 200 micrometres. These values for the thickness of the second upper layer are particularly advantageous to optimise the amount of conductive material, for example conductive adhesive, which must be used to make the electrical contact between the photovoltaic cells of the module that contains the conductive interconnection structure according to the present invention and the conductive layer of the conductive structure and, at the same time, to ensure the conformability of the second upper layer to the system, i.e. to ensure that the thickness of the second upper layer is sufficient to correctly encapsulate the conductive layer arranged below the second upper layer and the solar cells of the final module.

According to a further embodiment of the present invention, a conductive interconnection structure is provided, wherein the predetermined layout of conductive material covers a fraction of surface of the first lower layer in the range from 5 to 50 percent of the total surface of the first lower layer, preferably from 10 to 15 percent. In this way, a large fraction of the total surface of the first lower layer is free. This thus makes it possible to optimise the fraction of radiation that can reach the photovoltaic cells from the rear side of the module and thus makes it particularly advantageous to apply the conductive interconnection structure to glass-glass photovoltaic modules with double-faced cells. Moreover, in this way the aesthetics of the system are substantially improved since the conductive interconnection structure has a substantially smaller surface of opaque areas of conductive material. This advantage is further implemented in the case in which the conductive interconnection structure is used for glass-glass modules to be used in BIPV (Building Integrated Photo Voltaic) and comprising back-contact solar cells. In this way visibly welded ribbons typically used for the connection of conventional solar cells, i.e. without back-contact, are avoided and, with the interconnection structure according to embodiments of the present invention, the aesthetics of the glass-glass module are substantially increased.

According to a further embodiment of the present invention, a conductive interconnection structure is provided, wherein the conductive interconnection structure is provided in reels. This solution is particularly advantageous since it makes it possible to substantially simplify the mounting process of a photovoltaic module. This is because, having an independent interconnection structure, it will be sufficient to apply the photovoltaic cells above such a structure so as to ensure an interconnection between the cells. In addition, thanks to the fact that said conductive interconnection structure is provided in a reel, it is also possible to have an excellent precision in the positioning of such a structure and to allow an extremely fast production in series of the photovoltaic modules.

According to a further embodiment of the present invention, a conductive interconnection structure is provided, wherein the conductive interconnection structure is supplied in sheets. This solution is particularly advantageous because it makes it possible to substantially simplify the mounting process of a photovoltaic module. This is because, having an independent interconnection structure, it will be sufficient to apply the photovoltaic cells above such a structure so as to ensure an interconnection between the cells. In addition, thanks to the fact that said conductive interconnection structure is supplied in sheets, it is also possible to have an excellent precision in the positioning of such a structure and have a minimum bulk in height, making it possible to be transported with extreme efficiency of space.

According to a further embodiment of the present invention, a photovoltaic module of the glass-glass type is provided comprising a first rear layer of glass, a second upper layer of glass and forming the main surface of the photovoltaic module, a plurality of solar cells and a conductive interconnection structure according to one of the embodiments of the present invention, wherein the solar cells are coupled with the first rear layer of glass through the conductive interconnection structure and wherein the solar cells are electrically connected to the conductive layer of the conductive interconnection structure. The photovoltaic module of the glass-glass type according to an embodiment of the present invention can thus be a photovoltaic module of the glass-glass type with back-contact cells. This family comprises for example the following types of solar cells: Interdigitated Back Contact (IBC) type cells, Emitter Wrap Through (EWP) type cells, Metal Wrap Through (MWT) type cells. The back-contact cells are advantageous since they make it possible to transfer the contact with both of the electrodes of the cell on the rear side of the cell, i.e. on the side not exposed to light radiation. This reduces the shading effect, i.e. reduction of the effective surface of the cell exposed to radiation, due to the presence of ohmic contacts on the front surface of the cell. Moreover, the photovoltaic module of the glass-glass type according to an embodiment of the present invention can comprise double-faced solar cells. The first rear layer of glass forms one of the two air-sides of the glass-glass photovoltaic module, in particular the rear air-side. The second upper layer of glass forms the second air-side of the glass-glass photovoltaic module, i.e. the main surface of the photovoltaic module directly facing towards the sun.

According to a further embodiment of the present invention, a photovoltaic module is provided, wherein the upper glass layer is coupled with the plurality of solar cells by means of a coupling layer comprising encapsulating material. This embodiment is particularly advantageous because the encapsulating material of the coupling layer between the solar cells and the upper glass layer adheres in an optimal manner to the encapsulating material of the second upper layer of the conductive interconnection structure and thus the stability of the system is optimised.

According to a further embodiment of the present invention, a method for producing a conductive interconnection structure for a glass-glass photovoltaic module according to one or more of the embodiments of the present invention described above is provided.

According to a further embodiment of the present invention, a method for producing a conductive interconnection structure to be applied to a photovoltaic module of the glass-glass type is provided comprising the following steps:

a) providing a first lower layer comprising encapsulating material;

b) providing a conductive layer comprising a predetermined layout of conductive material; and

c) providing a second upper layer comprising encapsulating material;

wherein the conductive layer is arranged between the first lower layer and the second upper layer.

The fact that the conductive interconnection structure made with the method based on the present invention is “to be applied” to a photovoltaic module of the glass-glass type means that the conductive interconnection structure made with the method based on the present invention is a product on its own, i.e. a product that is made independently and separately with respect to the photovoltaic module and that, once made, will subsequently be incorporated in the photovoltaic module while it is made.

According to a further embodiment of the present invention, a method is provided in which the conductive layer is in direct contact with the encapsulating material of the first lower layer.

Preferably, making the conductive layer comprising a predetermined layout of conductive material is carried out with techniques that do not need high temperatures, for example mechanical subtractive techniques like milling or additive techniques in which the predetermined layout is obtained by positioning elements of conductive material pre-formed on the surface of the first lower layer.

The adhesion between the various layers of the interconnection structure can be obtained through lamination techniques, for example hot lamination at temperatures in the range from 60° C. to 110° C.

According to a further embodiment of the present invention, a method for producing a conductive interconnection structure is provided in which at least one or both of steps a) and c) respectively for supplying the first lower layer and for supplying the second upper layer comprises a co-extrusion step carried out so as to obtain a layer of dielectric material arranged between a layer of thermo-adhesive material and a layer of encapsulating material. The co-extrusion can for example be carried out as described in WO 2013/182954 A1 with reference to “co-extrusion”. The teaching of WO 2013/182954 A1 is incorporated here in its entirety. The co-extrusion can also be carried out for example as described in Italian patent application No. 102012902092055 (VI2012A000267) the teaching of which is incorporated here in its entirety.

According to a further embodiment of the present invention, the second upper layer comprising encapsulating material is perforated so as to make a plurality of through holes, wherein one or more of the through holes is at a conductive region of the predetermined layout of conductive material. The perforation can be carried out with laser techniques. The perforation can take place before the second upper layer is fixed to the conductive layer and/or to the first lower layer. Alternatively, the perforation can take place after the second upper layer has been fixed to the system.

According to a further embodiment of the present invention, a method for producing a conductive interconnection structure is provided in which step b) of supplying a conductive layer comprises a step of milling and/or removing conductive material in order to obtain said predetermined layout of conductive material. For example, based on an embodiment of the present invention, a sheet of conductive material can be arranged on the first lower layer and then fixed to it. The predetermined layout of conductive material can thus be obtained through mechanical ablation or milling techniques. For example, the predetermined layout of conductive material can be obtained with the methods described in WO 2014/068496 A2, the teaching of which is incorporated here in its entirety. Alternatively, the predetermined layout of conductive material can be obtained with chemical etching techniques, for example with a definition process of the layout based on photolithographic techniques followed by a chemical etching to remove the excess material. This solution makes it possible to reach a high precision in the positioning of the conductors using extremely precise cutting machines. Moreover, thanks to this method, it is possible to have a perfectly flat surface of the conductive material.

According to a further embodiment of the present invention, a method for producing a conductive interconnection structure is provided in which step b) of providing a conductive layer comprises the preparation of a plurality of elements of conductive material and the positioning of the elements of conductive material on the surface of the first lower layer so as to obtain the predetermined layout of conductive material. Based on this embodiment, the layout of the conductive layer of the conductive interconnection structure is made in an additive manner by suitably positioning elements of conductive material on the surface of the first lower layer so as to make the predetermined layout of conductive material and avoiding having to remove, for example by milling or by chemical etching, conductive material after the elements of conductive material have been positioned on the first lower layer. For example, the entire layout of the conductive layer can be obtained thanks to the positioning of a plurality of elements of conductive material on the surface of the first lower layer, thus eliminating the need to remove conductive material after it has been fixed to the first lower layer.

Based on a particularly advantageous embodiment of the present invention, the choice on the use of additive techniques like those described in the previous paragraphs or of subtractive techniques that foresee the removal of conductive material in order to form the conductive layer is based on the coverage value of the predetermined layout of conductive material with respect to the total surface of the first lower layer. For example, if the predetermined layout of conductive material covers 70% or less of the total surface of the first lower layer, preferably 50% or less, even more preferably 15% or less, then additive techniques like those described in the previous paragraph are used. If, on the other hand, the predetermined layout of conductive material covers 80% or more of the total surface of the first lower layer, then subtractive techniques are used, like for example milling, laser ablation or chemical etching. For coverage fractions between 70% and 80% it is possible, for example, to use additive techniques or subtractive techniques without distinction.

According to a further embodiment of the present invention, a method for producing a conductive interconnection structure is provided in which the conductive interconnection structure is rolled so as to form a reel. This solution is particularly advantageous since it then makes it possible to substantially simplify the mounting process of a photovoltaic module. This is because, having an independent interconnection structure, it will be sufficient to apply the photovoltaic cells above such a structure so as to ensure an interconnection between the cells. In addition, thanks to the fact that said conductive interconnection structure is supplied in a reel, it is also possible to have an excellent precision in the positioning of such a structure and to allow an extremely fast production in series of the photovoltaic modules.

According to a further embodiment of the present invention, a method for producing a conductive interconnection structure is provided in which the conductive interconnection structure is cut so as to form sheets. This solution is particularly advantageous because it then makes it possible to substantially simplify the mounting process of a photovoltaic module. This is because, having an independent interconnection structure, it will be sufficient to apply the photovoltaic cells above such a structure so as to ensure an interconnection between the cells. In addition, thanks to the fact that said conductive interconnection structure is supplied in sheets, it is also possible to have excellent precision in the positioning of such a structure and to have minimal bulk in height, for example allowing it to be transported with extreme efficiency of space.

According to a further embodiment of the present invention, a method for producing a photovoltaic module of the glass-glass type is provided comprising a first rear layer of glass, a second upper layer of glass and forming the main surface of the photovoltaic module and a plurality of solar cells, the method comprising the following steps:

a) formation of a conductive interconnection structure according to the method of one of the embodiments of the present invention;

b) coupling the solar cells with the conductive interconnection structure so that the solar cells are electrically connected to the conductive layer of the conductive interconnection structure. In this way, it is possible to make, for example, a glass-glass photovoltaic module with back-contact solar cells.

The method according to the present invention can also comprise the coupling of the first rear layer of glass with the second upper layer of glass by means of the conductive interconnection structure.

The adhesion between the various layers of the photovoltaic module can be obtained through lamination techniques, for example hot lamination at temperatures in the range from 130° C. to 170° C.

### BRIEF DESCRIPTION OF THE FIGURES

The present invention will be described with reference to the attached figures in which the same reference numerals and/or marks indicate the same parts and/or similar and/or corresponding parts of the system. In the figures:

FIG. 1 schematically shows a conductive interconnection structure for a photovoltaic module of the glass-glass type according to an embodiment of the present invention;

FIG. 2 schematically shows the structure of the first lower layer of a conductive interconnection structure for a photovoltaic module of the glass-glass type according to an embodiment of the present invention;

FIG. 3 schematically shows the structure of the second upper layer of a conductive interconnection structure for a photovoltaic module of the glass-glass type according to an embodiment of the present invention;

FIG. 4 schematically shows a photovoltaic module of the glass-glass type comprising a conductive interconnection structure according to an embodiment of the present invention.

### DETAILED DESCRIPTION

Hereinafter, the present invention is described with reference to particular embodiments, as illustrated in the attached figures. However, the present invention is not limited to the particular embodiments described in the following detailed description and represented in the figures, but rather the described embodiments exemplify simply the various aspects of the present invention, the purpose of which is defined by the claims. Further modifications and variations of the present invention will become clear to those skilled in the art.

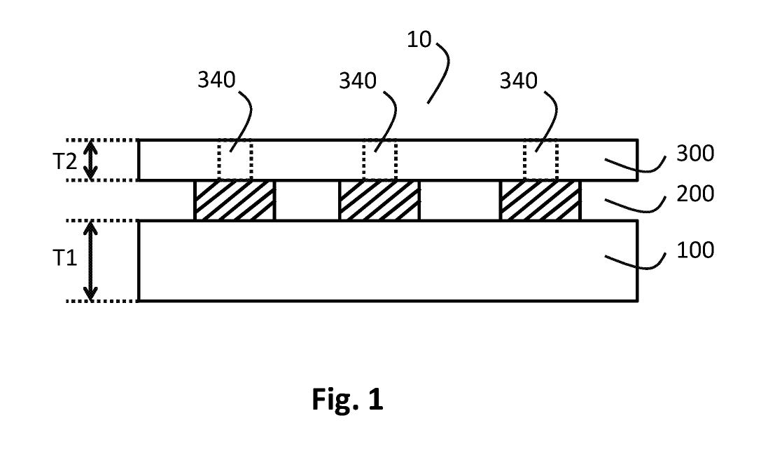

FIG. 1 schematically shows a conductive interconnection structure 10 for a photovoltaic module of the glass-glass type according to an embodiment of the present invention.

The conductive interconnection structure comprises a conductive layer 200 comprising a predetermined layout of conductive material. The predetermined layout can have different configurations and is configured so as to form one or more connection circuits for the photovoltaic cells of the glass-glass photovoltaic module to which the conductive interconnection structure 10 is applied. Moreover, the predetermined layout can be configured to provide a connection between the outside and the glass-glass photovoltaic module to which the conductive interconnection structure 10 is applied, for example to connect together different photovoltaic modules, or to connect the photovoltaic module to any component of a photovoltaic installation.

The conductive material of the conductive layer 200 can comprise copper. Moreover or alternatively, the conductive material can comprise aluminium. Moreover, in particular in the case in which the conductive material comprises aluminium, the conductive material can comprise a conductive metallic layer on its surface. The conductive metallic layer can comprise silver or a metallic alloy comprising silver, or copper or a metallic alloy comprising copper and it can for example have a thickness comprised between 12 nm and 200 nm and, preferably, between 40 nm and 100 nm.

The thickness of the conductive layer 200 can be comprised in the range from 18 micrometres to 200 micrometres.

The conductive interconnection structure 10 further comprises a first lower layer 100. The conductive layer 200 is arranged above the first lower layer 100 and is directly in contact with it. The first lower layer 100 comprises encapsulating material.

The encapsulating material of the first lower layer 100 can comprise EVA (ethylene vinyl acetate). According to alternative embodiments of the present invention, the encapsulating material of the first lower layer 100 comprises at least one of the following materials: silicones, ionomer resins, thermo polyurethanes, polyolefins, thermo polyolefins, terpolymers seamed with maleic anhydride, PVB (polyvinylbutyrral).

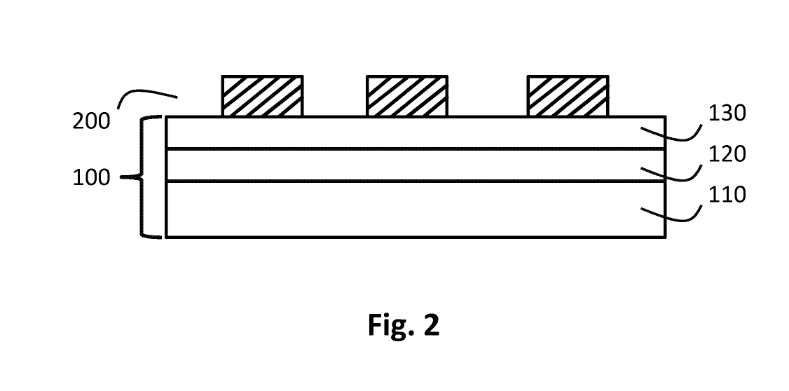

The first layer 100 can be a mono-layer, i.e. a single layer of encapsulating material, for example a single layer of thermo-adhesive material, as shown schematically in FIG. 1. Alternatively, as will be described in detail hereinafter with reference to FIG. 2, the first layer 100 can have a multi-layer structure.

The conductive interconnection structure 10 further comprises a second upper layer 300. The conductive layer 200 is arranged between the first lower layer 100 and the second upper layer 300 and is thus arranged below the second upper layer 300 and is directly in contact with it. The second upper layer 300 comprises encapsulating material.

The encapsulating material of the second upper layer 300 can comprise EVA (ethylene vinyl acetate). According to alternative embodiments of the present invention, the encapsulating material of the second upper layer 300 comprises at least one of the following materials: silicones, ionomer resins, thermo polyurethanes, polyolefins, thermo polyolefins, terpolymers seamed with maleic anhydride, PVB (polyvinylbutyrral).

Advantageously, the encapsulating material of the second upper layer 300 is identical to the encapsulating material of the first lower layer 100 so as to optimise the adhesion and thus the stability of the system. Moreover, it is possible to obtain this effect by combining two encapsulating materials that are different but compatible with each other.

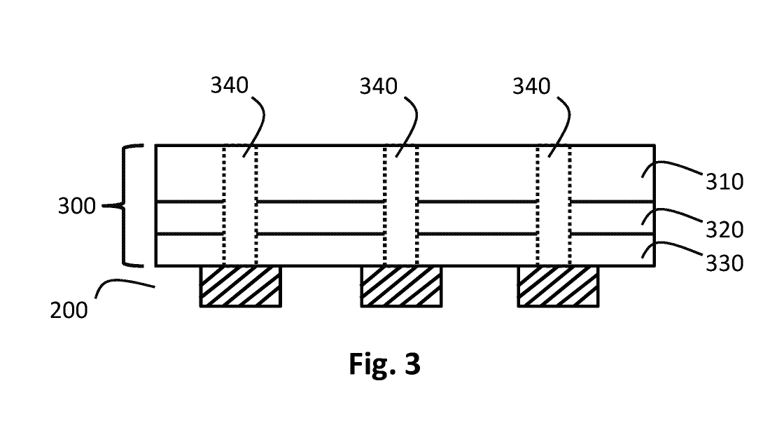

Similarly to the first layer 100, the second upper layer 300 can also be a mono-layer, i.e. a single layer of encapsulating material, for example a single layer of thermo-adhesive material, as shown schematically in FIG. 1. Alternatively, as will be described in detail hereinafter with reference to FIG. 3, the second layer 300 can have a multi-layer structure.

The second upper layer 300 comprises a plurality of through holes 340. The through holes 340 are made at the conductive regions of the conductive layer 200 so as to expose at least part of the surface of the conductive regions of the conductive layer 200. Advantageously, the conductive regions of the conductive layer 200 comprise connection pads, which represent the points of the connection circuit to be placed in electrical connection with a contact at one of the electrodes formed on the surface of the photovoltaic cells of the module to which the interconnection structure 10 will be applied and the through holes 340 of the second upper layer 300 are made at these connection pads so as to expose them.

In the architecture of a glass-glass photovoltaic module comprising the conductive interconnection structure 10 the through holes 340 can thus be used to house conductive adhesive so as to make the electrical connection between the photovoltaic cells of the module and the conductive layer 200 of the interconnection structure 10.

The through holes 340 can be made in the second upper layer 300 by means of laser techniques or by punching. The through holes 340 can be made before or after the second upper layer 300 has been fixed to the conductive layer 200.

FIG. 1 schematically shows the thicknesses T1 and T2 of the first lower layer 100 and of the second upper layer 300, respectively. Preferably, the thickness T1 is greater than the thickness T2.

The thickness T1 of the first layer 100 can for example be comprised in the range from 200 micrometres to 500 micrometres, preferably from 300 micrometres to 400 micrometres, even more preferably it is equal to 350 micrometres. The thickness T2 can, on the other hand, be comprised in the range from 100 micrometres to 300 micrometres, preferably from 150 micrometres to 250 micrometres, even more preferably it is equal to 200 micrometres.

Moreover, irrespective of the absolute values of the thicknesses T1 and T2, the ratio between the thickness T1 and the thickness T2 can be in the range from 1.5 to 2.5, preferably from 1.5 to 2.0, even more preferably it is equal to 1.75.

FIG. 2 schematically shows the structure of the first lower layer 100 of a conductive interconnection structure 10 according to an embodiment of the present invention. The conductive layer 200 arranged above the first lower layer 100 is also schematically shown.

According to the embodiment shown in FIG. 2, the first lower layer 100 has a multi-layer structure. In particular, the first lower layer 100 comprises a layer of dielectric material 120 arranged between a layer of thermo-adhesive material 130 and a layer of encapsulating material 110. The layer of thermo-adhesive material 130 is directly in contact with the conductive layer 200, in particular with the predetermined layout of conductive material formed in the conductive layer 200. The layer of thermo-adhesive material 130 is advantageous because it optimises the adhesion of the conductive layer 200 to the first lower layer 100, ensuring the stability of the system and the workability. Moreover, the layer of thermo-adhesive material 130 makes it possible to encapsulate and thus effectively englobe the channels of the predetermined layout of conductive material. The layer of encapsulating material 110 ensures adequate adhesion of the conductive interconnection structure 100 to the rear glass layer of a glass-glass photovoltaic module and ensure the encapsulation and therefore the optimal englobing of the entire structure of the module.

The structure of the lower layer 100 can be like the multi-layer structure described in WO 2014/182954 A2.

In particular, the layer of dielectric material 120 can comprise a thin inextensible film. According to an embodiment of the present invention, the layer of dielectric material 120 comprises a polymer. According to particular embodiments of the present invention, the layer of dielectric material 120 comprises polyethylene terephthalate (PET), polypropylene (PP) or polyimide (PI) or other polymers that have characteristics of mechanical stability and dielectric rigidity. Preferably, the layer of dielectric material 120 can also comprise co-extruded PP. According to an embodiment of the present invention, the layer of dielectric material 120 has a thickness comprised between 40 and 150 micrometres. Preferably, the layer of dielectric material 120 has a thickness comprised between 23 and 36 micrometres.

PP is particularly advantageous for the layer 120 because thanks to its thermodynamic characteristics, in particular the fact that its melting temperature is slightly greater than the temperatures at which lamination typically occurs, it ensures the mechanical stability of the system and avoids the undesired movement of the circuit inside the module during the production of the module itself. Moreover, PP at the same time ensures the ability to shape itself to the inner parts of the module. Moreover, using PP as material for the layer of dielectric material 120 it is possible to make the lower layer 100 advantageously in a single co-extrusion process.

The layer of thermo-adhesive material 130 ensures the adhesion of the conductive layer 200 to the first lower layer 100. Moreover, the thermo-adhesive material is capable of shaping itself according to the different heights of the structure of the layout of conductive material and thus filling possibly empty spaces present in the twists and turns of the layout of conductive material.

The layer of thermo-adhesive material 130 can comprise a resin. For example, the layer of thermo-adhesive material 130 can comprise a thermosetting resin or a thermoplastic resin. Moreover, the layer of thermo-adhesive material 130 can comprise a resin selected among epoxy resins, epoxy-phenolic resins, or copolyester resins, or polyurethane resins or ionomer polyolefin. The layer of thermo-adhesive material 130 can comprise a resin the melting temperature of which is comprised between 60° C. and 160° C. Preferably, the resin of the layer of thermo-adhesive material 130 is not sticky if managed cold.

According to a further embodiment of the present invention, the layer of thermo-adhesive material 130 comprises an encapsulating material. According to a particular embodiment, the layer of thermo-adhesive material 130 comprises EVA. According to other embodiments of the present invention, the layer of thermo-adhesive material 130 comprises at least one of the following materials: silicones, ionomer resins, thermo-polyurethanes, polyolefins, thermo-polyolefins, terpolymers seamed with maleic anhydride.

The use of a layer 130 comprising an encapsulating material brings the advantages determined by high fluidity thereof at the lamination temperatures. Fluidity that, even with low thicknesses, makes it possible to have the material (for example EVA) capable of filling the empty spaces left by the conductive layer where it is possibly ablated. Moreover, the encapsulation EVA as well as the ionomer resins, by their nature, have an excellent adhesion to metallic surfaces such as copper and aluminium. Lastly, the uniformity of the materials between layer 110 and layer 130 generates a lesser chemical complexity of the system.

The thickness of the layer of thermo-adhesive material 130 can vary in the range from 50 micrometres to 200 micrometres.

The first lower layer 100 also comprises a layer of encapsulating material 110 arranged on the opposite surface of the layer of dielectric material 120 with respect to the surface on which the layer of thermo-adhesive material 130 is arranged.

According to an embodiment of the present invention, the layer of encapsulating material 110 comprises EVA. According to other embodiments of the present invention the layer of encapsulating material 110 comprises at least one of the following materials: silicones, ionomer resins, thermo polyurethanes, polyolefins, thermo polyolefins, terpolymers seamed with maleic anhydride, PVB (polyvinylbutyrral).

According to an embodiment of the present invention, the layer of encapsulating material 110 has a thickness comprised between 50 and 200 micrometres.

The layer of encapsulating material 110 is particularly advantageous because it facilitates the adhesion of the conductive interconnection structure 10 to the rear glass layer of the glass-glass module. In this way, the stability of the system is optimised. In particular, during a lamination process for producing the glass-glass photovoltaic module, the encapsulating material can melt and adhere in an optimal manner to the glass of the rear layer of the glass-glass module.

FIG. 3 schematically shows the structure of the second upper layer 300 of a conductive interconnection structure 10 for a photovoltaic module of the glass-glass type according to an embodiment of the present invention. The conductive layer 200 arranged below the second upper layer 300 is also schematically shown.

According to the embodiment shown in FIG. 3, the second upper layer 300 has a multi-layer structure. In particular, the second upper layer 300 comprises a layer of dielectric material 320 arranged between a layer of thermo-adhesive material 330 and a layer of encapsulating material 310. The layer of thermo-adhesive material 330 is directly in contact with the conductive layer 200, in particular with the predetermined layout of conductive material formed in the conductive layer 200. The layer of thermo-adhesive material 330 is advantageous because it optimises the adhesion of the conductive layer 200 to the second upper layer 300, ensuring the stability of the system and workability. Moreover, the layer of thermo-adhesive material 330 makes it possible to encapsulate and thus englobe the channels of the predetermined layout of conductive material. The layer of encapsulating material 310 ensures adequate adhesion of the conductive interconnection structure 100 to the upper glass layer of a glass-glass photovoltaic module and ensure the encapsulation and therefore the optimal englobing of the entire structure of the module.

The structure of the upper layer 300 can be like the multi-layer structure described in WO 2014/182954 A2.

In particular, the layer of dielectric material 320 can comprise an inextensible thin film. According to an embodiment of the present invention, the layer of dielectric material 320 comprises a polymer. According to particular embodiments of the present invention, the layer of dielectric material 320 comprises polyethylene terephthalate (PET), polypropylene (PP) or polyimide (PI) or other polymers that have characteristics of mechanical stability and dielectric rigidity. Preferably, the layer of dielectric material 320 can comprise co-extruded PP. According to an embodiment of the present invention, the layer of dielectric material 320 has a thickness comprised between 40 and 150 micrometres. Preferably, the layer of dielectric material 320 has a thickness comprised between 23 and 100 micrometres. Preferably, the layer 320 has a thickness of 60 micrometres.

PP is particularly advantageous for the layer 320 because thanks to its thermodynamic characteristics, in particular the fact that its melting temperature is slightly greater than the temperatures at which lamination typically occurs, it ensures the mechanical stability of the system and avoids the undesired movement of the solar cells inside the module during the production of the module itself. Moreover, PP ensures a constant electrical insulation between the layout of conductive material and the solar cells. Moreover, using PP as material for the layer of dielectric material 320 it is possible to make the upper layer 300 advantageously in a single co-extrusion process.

The layer of thermo-adhesive material 330 ensures the adhesion of the conductive layer 200 to the second upper layer 300. Moreover, the thermo-adhesive material is capable of shaping itself according to the different heights of the structure of the layout of conductive material and thus filling possibly empty spaces present. Moreover, the presence of the layers of thermo-adhesive material 130 and 330 that are opposite and enclose the layout of conductive material of the conductive layer 200 promotes a stable adhesion of the system thanks to the interaction of the materials of the two layers of thermo-adhesive material in the interspaces present in the predetermined layout of conductive material of the conductive layer 200.

The layer of thermo-adhesive material 330 can comprise a resin. For example, the layer of thermo-adhesive material 330 can comprise a thermosetting resin or a thermoplastic resin. Moreover, the layer of thermo-adhesive material 330 can comprise a resin selected among epoxy resins, epoxy-phenolic resins, or copolyester resins, or polyurethane resins or ionomer polyolefin. The layer of thermo-adhesive material 330 can comprise a resin the melting temperature of which is comprised between 60° C. and 160° C. Preferably, the resin of the layer of thermo-adhesive material 330 is not sticky if managed cold.

According to a further embodiment of the present invention, the layer of thermo-adhesive material 330 comprises an encapsulating material. According to a particular embodiment, the layer of thermo-adhesive material 330 comprises EVA. According to other embodiments of the present invention, the layer of thermo-adhesive material 330 comprises at least one of the following materials: silicones, ionomer resins, thermo-polyurethanes, polyolefins, thermo-polyolefins, terpolymers seamed with maleic anhydride.

The use of a layer 330 comprising an encapsulating material leads to the advantages determined by the high fluidity thereof at the lamination temperatures. Said fluidity, even with low thicknesses, makes it possible to have the material (for example EVA) capable of filling the empty spaces left by the conductive layer where it is possibly ablated. Moreover, the encapsulation EVA as well as the ionomer resins, by their nature, have an excellent adhesion to metallic surfaces such as copper and aluminium. Lastly, the uniformity of the materials between layer 310 and layer 330 generates a lower chemical complexity of the system.

The thickness of the layer of thermo-adhesive material 330 can vary in the range from 50 micrometres to 200 micrometres. Preferably, the layer of thermo-adhesive material 330 has a thickness of 70 micrometres.

The second upper layer 300 also comprises a layer of encapsulating material 310 arranged on the opposite surface of the layer of dielectric material 120 with respect to the surface on which the layer of thermo-adhesive material 330 is arranged.

According to an embodiment of the present invention, the layer of encapsulating material 310 comprises EVA. According to other embodiments of the present invention the layer of encapsulating material 310 comprises at least one of the following materials: silicones, ionomer resins, thermo polyurethanes, polyolefins, thermo polyolefins, terpolymers seamed with maleic anhydride, PVB (polyvinylbutyrral).

According to an embodiment of the present invention, the layer of encapsulating material 310 has a thickness comprised between 50 and 200 micrometres. Preferably, the layer of encapsulating material 310 has a thickness of 70 micrometres.

The layer of encapsulating material 310 is particularly advantageous because it facilitates the adhesion of the conductive interconnection structure 10 to the upper glass layer of the glass-glass photovoltaic module. In this way, the stability of the system is optimised.

As shown in FIG. 3, also in the case of a multi-layer structure, the second upper layer 300 can comprise a plurality of through holes 340 arranged at a conductive region of the predetermined layout of conductive material. In particular, the through holes 340 pass through all of the layers of the second upper layer 300.

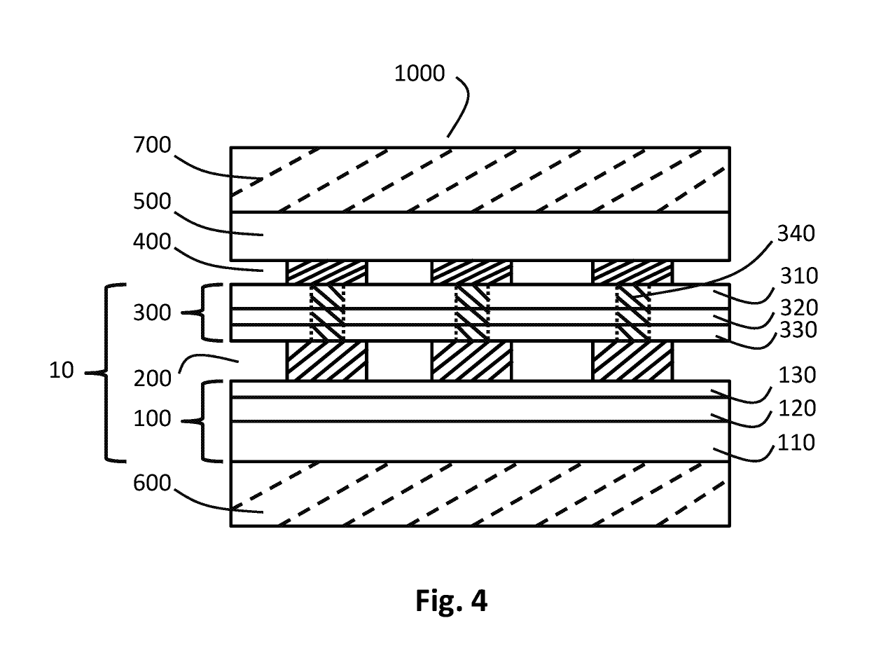

FIG. 4 schematically shows a photovoltaic module 1000 of the glass-glass type comprising a conductive interconnection structure 10 according to an embodiment of the present invention.

As shown in the figures, the conductive interconnection structure 10 is an independent structure that can thus be provided, for example commercialised, as a single unit before the mounting operations of the photovoltaic module 1000. The interconnection structure 10 will thus be subsequently englobed in the photovoltaic module while it is made.

The photovoltaic module 1000 comprises a first rear layer of glass 600 that forms the rear air-side of the module. The photovoltaic module also comprises a second upper layer of glass 700 that forms the upper air-side of the module. In particular, the second upper layer of glass 700 forms the main surface of the glass-glass photovoltaic module 1000, i.e. the surface facing towards the sun.

The thicknesses of the layers of glass 600 and 700 can for example vary in the range from 2 mm to 5 mm.

The photovoltaic module 1000 comprises a plurality of solar cells 400. In particular, in the example shown in the figures, the solar cells 400 are back-contact solar cells.

As can be seen from the figure, the solar cells 400 are coupled with the first rear layer of glass 600 of the module 1000 by means of a conductive interconnection structure 10. Moreover, the solar cells 400 are electrically connected to the conductive layer 200 of the conductive interconnection structure 10. In particular, the electrical connection is made through conductive adhesive housed in the through holes 340 of the second upper layer 300 of the interconnection structure 10.

The interconnection structure 10 has a multi-layer structure as described in detail above with reference to FIGS. 2 and 3.

The upper glass 700 is coupled with the plurality of solar cells 400 by means of a coupling layer 500 comprising encapsulating material. The coupling layer 500 can comprise EVA. According to other embodiments of the present invention the coupling layer 500 comprises at least one of the following materials: silicones, ionomer resins, thermo polyurethanes, polyolefins, thermo polyolefins, terpolymers seamed with maleic anhydride, PVB (polyvinylbutyrral). The thicknesses of the coupling layer 500 can vary from 250 to 500 micrometres.

The presence of the layer of encapsulating material 310 of the second upper layer 300 of the conductive interconnection structure 10 promotes a stable adhesion of the system thanks to its interaction with the encapsulating material of the coupling layer 500 in the interspaces between the solar cells 400. In particular, following a possible lamination process for the formation of the photovoltaic module, the encapsulating material 310 of the second upper layer and the encapsulating material of the coupling layer 500 come into contact in the interspaces between the solar cells 400 and adhere to one another, for example they could melt together and adhere in these interspaces.

Similarly, the presence of the layer of encapsulating material 110 of the first upper layer 100 of the conductive interconnection structure 10 promotes a stable adhesion of the system thanks to the adhesion between the interconnection structure 10 and the rear glass layer 600. According to an alternative embodiment of the invention, the system is provided with a further layer of encapsulating material arranged between the rear glass layer 600 and the first lower layer 100 of the conductive interconnection structure 10 to further improve the stability of the system.

Moreover, as described above, the presence of the layers of thermo-adhesive material 130 and 330 promotes a stable adhesion of the system thanks to the interaction of the materials of the two layers in the interspaces present in the predetermined layout of conductive material of the conductive layer 200.

The stability of the glass-glass photovoltaic module 1000 is thus optimised.

According to an embodiment of the present invention, a method for producing a conductive interconnection structure 10 is provided. The method comprises the following steps:

a) providing a first lower layer 100 comprising encapsulating material;

b) providing a conductive layer 200 comprising a predetermined layout of conductive material;

and

c) providing a second upper layer 300 comprising encapsulating material;

wherein the conductive layer 200 is arranged between the first lower layer 100 and the second upper layer 300.

The first lower layer 100 can comprise a multi-layer structure and be made for example by co-extrusion. Similarly, the second upper layer 300 can comprise a multi-layer structure and be made for example by co-extrusion.

Advantageously, the conductive layer 200 is made above the first lower layer 100 in the case in which the first lower layer 100 has a greater thickness with respect to the second upper layer 300.

The conductive layer 200 can be made above the first lower layer 100 in an additive manner, i.e. positioning different elements of conductive material on the first lower layer 100 so as to form the predetermined layout of conductive material through the assembly of the various elements.

Moreover, the conductive layer 200 can be made above the first lower layer 100 in a subtractive manner, i.e. using techniques that foresee the removal of conductive material after a continuous sheet of conductive material has been arranged on the first lower layer 100 in order to obtain a predetermined layout of conductive material. This solution makes it possible to reach a high precision in the positioning of the conductors using extremely precise cutting machines. Moreover, thanks to this method, it is possible to have a perfectly flat surface of the conductive material 200. On the other hand, in the case in which conductive wires are used instead of such a conductive layer 200, there would be two main drawbacks. The first drawback consists of having extreme difficulty in obtaining a flat surface of the conductive material. The second drawback, on the other hand, consists of having difficulty in the positioning and in the adhesion of the various conductive wires to the first lower layer 100.

The adhesion between the various layers of the interconnection structure can be obtained through lamination techniques, for example hot lamination at temperatures in the range from 60° C. to 100° C. It is also possible to foresee a lamination in two steps in which in a first step the conductive layer 200 is fixed to the first lower layer 100 and in a second step the second upper layer 300 is fixed to the system obtained in the first step.

The second upper layer 300 comprising encapsulating material is perforated so as to make a plurality of through holes 340, wherein one or more of the through holes is at a conductive region of the predetermined layout of conductive material of the layer 200. The perforation can be carried out with laser techniques. The perforation can take place before the second upper layer 300 is fixed to the conductive layer 200 and/or to the first lower layer 100. Alternatively, the perforation can take place after the second upper layer 300 has been fixed to the system.

The total thickness of the conductive interconnection structure 10 obtained can vary in the range from 300 micrometres to 800 micrometres.

The conductive interconnection structure 10 can be supplied in reels, i.e. in the form of a band wound in a destination reel or directly in sheets having the lateral dimensions of the photovoltaic modules to be produced. Typical lateral dimensions of the sheets are from 800 to 1000 mm in width.

According to a further embodiment of the present invention, a method for producing a photovoltaic module of the glass-glass type 1000 is provided comprising a first rear layer of glass 600, a second upper layer of glass 700 and forming the main surface of the photovoltaic module and a plurality of solar cells 400, the method comprising the following steps:

a) formation of a conductive interconnection structure 10 according to the method of one of the embodiments of the present invention;

b) coupling the solar cells 400 with the conductive interconnection structure 10 so that the solar cells 400 are electrically connected to the conductive layer 200 of the conductive interconnection structure 10.

In particular, according to an embodiment of the present invention the following steps are carried out in the order in which they are listed:

1) Preparation of a rear glass layer 600;

2) Coupling a conductive interconnection structure 10 according to the present invention with the rear glass layer 600;

3) Filling the through holes 340 of the second upper layer 300 of the interconnection structure 10 with conductive adhesive;

4) Application of a plurality of solar cells 400 to the system so as to make the electrical contact between the solar cells 400 and the conductive layer 200 of the conductive interconnection structure 10 by means of the conductive adhesive housed in the through holes 340;

5) Application of a layer of encapsulating material 500 above the solar cells 400;

6) Application of an upper glass layer 700 above the layer of encapsulating material 500;

7) Lamination of the system so as to cause the adhesion of the various layers.

Alternatively, according to another embodiment of the present invention, it is possible to start from the structure 10, which can be kept adhering to the support and flat by a vacuum system, and then the module is made according to the aforementioned steps 3), 4), 5), 6), then the system is inverted and the rear glass layer 600 is rested above.

Even though the present invention has been described with reference to the embodiments described above, it is clear to those skilled in the art that it is possible to make different modifications, variations and improvements of the present invention in light of the teaching described above and in the attached claims, without straying from the object and the scope of protection of the invention.

For example, the dimensions of the systems obtained based on the present invention can be various. Moreover, even though the case in which the solar cells of the module are back-contact solar cells has been described explicitly, the conductive interconnection structure based on the present invention can also be implemented in glass-glass modules in which the solar cells are arranged based on shingling technology.

Finally, the fields that are considered known by those skilled in the art have not been described to avoid needlessly excessively blurring the described invention.

Consequently, the invention is not limited to the embodiments described above, but is only limited by the scope of protection of the attached claims.

1. Conductive interconnection structure to be applied to a photovoltaic module of the glass-glass type comprising:
a conductive layer comprising a predetermined layout of conductive material;
a first lower layer comprising encapsulating material;
a second upper layer comprising encapsulating material;
wherein said conductive layer is arranged between said first lower layer and said second lower layer.

2. Conductive structure according to claim 1, wherein said conductive layer is in direct contact with the encapsulating material of said first lower layer.

3. Conductive structure according to claim 1, wherein said conductive layer is in direct contact with the encapsulating material of said second upper layer.

4. Conductive structure according to claim 1, wherein said second upper layer comprises a plurality of through holes, wherein one or more of the plurality of through holes is at a conductive region of the predetermined layout of conductive material.

5. Conductive structure according to claim 1, wherein said first lower layer comprises a layer of dielectric material arranged between a layer of thermo-adhesive material and a layer of encapsulating material.

6. Conductive structure according to claim 1, wherein said second upper layer comprises a layer of dielectric material arranged between a layer of thermo-adhesive material and a layer of encapsulating material.

7. Conductive structure according to claim 1, wherein the thickness of said first lower layer is greater than the thickness of said second upper layer, for example in which the ratio between the thickness of said first lower layer and the thickness of said second upper layer is in the range from 1.5 to 2.5, preferably from 1.5 to 2.0, even more preferably it is equal to 1.75.

8. Conductive structure according to claim 1, wherein the thickness of said first lower layer is comprised in the range from 250 micrometres to 500 micrometres, preferably from 300 micrometres to 400 micrometres, even more preferably it is equal to 350 micrometres.

9. Conductive structure according to claim 1, wherein the thickness of said second upper layer is comprised in the range from 100 micrometres to 300 micrometres, preferably from 150 micrometres to 250 micrometres, even more preferably it is equal to 200 micrometres.

10. Conductive structure according to claim 1, wherein said predetermined layout of conductive material covers a fraction of a surface of said first lower layer in the range from 5 to 50 percent of the surface of said first lower layer, preferably from 10 to 15 percent.

11. Conductive structure according to claim 1, wherein said conductive interconnection structure is supplied in reels.

12. Conductive structure according to claim 1, wherein said conductive interconnection structure is supplied in sheets.

13. Photovoltaic module of the glass-glass type comprising a first rear layer of glass, a second upper layer of glass and forming a main surface of the photovoltaic module, a plurality of solar cells and a conductive interconnection structure according to claim 1, wherein said plurality of solar cells are coupled with said first rear layer of glass through said conductive interconnection structure and wherein said plurality of solar cells are electrically connected to a conductive layer of said conductive interconnection structure.

14. Photovoltaic module according to claim 13, wherein said upper glass layer is coupled with the plurality of solar cells by means of a coupling layer comprising encapsulating material.

15. Method for producing a conductive interconnection structure to be applied to a photovoltaic module of the glass-glass type comprising the following steps:
a) supplying a first lower layer comprising encapsulating material;
b) supplying a conductive layer comprising a predetermined layout of conductive material;
c) supplying a second upper layer comprising encapsulating material;
wherein said conductive layer is arranged between said first lower layer and said second upper layer.

16. Method according to claim 15, wherein at least one or both of said steps a) and c) respectively for supplying said first lower layer and for supplying said second upper layer comprises a co-extrusion step carried out so as to obtain a layer of dielectric material arranged between a layer of thermo-adhesive material and a layer of encapsulating material.

17. Method according to claim 15, wherein said step b) for supplying a conductive layer comprises a step of milling and/or removing conductive material in order to obtain said predetermined layout of conductive material.

18. Method according to claim 15, wherein said step b) for supplying a conductive layer comprises preparation of a plurality of elements of conductive material and positioning of said plurality of elements of conductive material on a surface of said first lower layer so as to obtain said predetermined layout of conductive material.

19. Method according to claim 15, wherein said conductive interconnection structure is rolled so as to form a reel.

20. Method according to claim 15, wherein said conductive interconnection structure is cut so as to form sheets.

21. Method for producing a photovoltaic module of the glass-glass type comprising a first rear layer of glass, a second upper layer of glass and forming a main surface of the photovoltaic module and a plurality of solar cells, said method comprising the following steps:
a) formation of a conductive interconnection structure according to the method of claims 15;
b) coupling said plurality of solar cells with said first rear layer of glass through said conductive interconnection structure so that said plurality of solar cells are electrically connected to the conductive layer of said conductive interconnection structure.
